(19) United States
(12) Patent Application Publication
(10) Pub. No.: US 2012/0099286 A1
(43) Pub. Date: Apr. 26, 2012

(54) ELECTRONIC APPARATUS

(75) Inventors: Suguru Suzuki, Tokyo (JP); Tsutomu Abe, Kanagawa (JP)

(73) Assignee: PANASONIC CORPORATION, Osaka (JP)

(21) Appl. No.: 13/382,507

(22) PCT Filed: Feb. 4, 2011
(86) PCT No.: PCT/JP2011/000647

§ 371 Date: Jan. 5, 2012

(30) Foreign Application Priority Data
Mar. 11, 2010 (JP) 2010-054641

(51) Int. Cl. H05K 7/12

(52) U.S. Cl. 361/769

(57) ABSTRACT

To provide an electronic apparatus that can prevent electronic components from being separated from a circuit board.

The electronic apparatus 10 includes a circuit board 25, an electronic component 28 mounted on the circuit board 25 via solder balls 26, a cover member 30 mounted on the circuit board 25 so as to surround and cover the electronic component 28 and a convex portion 34 provided at the top plate portion 32 of the cover member 30. The convex portion 34 is deformable to a second state protruding on the circuit board 25 side from a first state protruding in the direction opposite to the circuit board 25 side. When the convex portion 34 is deformed in the second state, the convex portion 34 thus deformed can be made in contact with the top portion 28a of the electronic component 28.

### TECHNICAL FIELD

The present invention relates to an electronic apparatus in which electronic components are mounted on a circuit board via solder balls and a cover member is mounted on the circuit board so as to surround and cover the electronic components.

### BACKGROUND TECHNIQUE

As the electronic apparatuses, fold-type portable terminals have been realized in each of which a lower housing and an upper housing are coupled to each other by means of a coupling portion provided therebetween so as to be foldable freely , and an operation portion and a display portions are provided at the lower housing and the upper housing, respectively.

In this fold-type portable terminal, as shown in FIG. 8, for example, the lower housing includes a circuit board 100, electronic components 101 are mounted on a circuit board 100, and the electronic components 101 thus mounted are surrounded and covered by a cover member 102.

In the cover member 102, a frame portion 102a for surrounding the outer peripheries 101a of the electronic components 101 and a top plate portion 102b for surrounding the top portions 101b of the electronic components 101 are formed integrally.

This cover member 102 surrounds and covers the electronic components 101.

The process for mounting the electronic components 101 on the circuit board 100 will be explained. First, as shown in FIG. 9, the electronic components 101 are mounted on a circuit board 100 via solder balls 105, then the cover member 102 (see FIG. 8) is placed on the circuit board 100 so as to cover the electronic components 101, and thereafter the circuit board 100 is passed through a reflow furnace.

When the circuit board 100 is passed through the reflow furnace, the solder balls 105 are melted, deformed and then solidified. As a result, the electronic components 101 are fixed (mounted) on the circuit board 100 (see a patent document 1, for example).

### <Prior Art Document>

### <Patent Document>

Patent Document 1: JP-A-2002-368481

### SUMMARY OF THE INVENTION

### Problems that the Invention is to Solve

In the circuit board 100 of the related art, since the solder balls are melted and deformed when passed through the reflow furnace, the heights of the top portions 101b of the electronic components 101 with respect to the circuit board 100 reduce by an amount S1 (see FIG. 9) after passing through the reflow furnace.

In contrast, since the solder balls 105 are not used in order to fix the cover member 102 to the circuit board 100, the height of the cover member 102 does not change after passing through the reflow furnace.

Thus, as shown in FIG. 8, there arises a gap S2 between the top portions 101b of the electronic components 101 after passing through the reflow furnace and the top plate portion 102b of the cover member 102. Therefore, if an impact is applied to the circuit board 100 in a manner that the electronic apparatus (fold-type portable terminal) is fallen, for example, the electronic components 101 may be separated from the circuit board 100.

This invention is made in order to solve the aforesaid problem of the related art and an object of the invention is to provide an electronic apparatus which can prevent electronic components from being separated from a circuit board.

### Means for Solving the Problems

This invention includes a circuit board; an electronic component which is mounted on the circuit board via solder balls; a cover member which is mounted on the circuit board so as to surround and cover the electronic component, and a convex portion which is provided at the a top plate portion of the cover member, wherein the convex portion is deformable to a second state protruding on the circuit board side from a first state protruding in a direction opposite to the circuit board side, and the convex portion contacts with a top portion of the electronic component in the second state.

According to the invention thus configured, since the convex portion deforms to the second state from the first state to thereby contact with the top portion of the electronic component, the top portion of the electronic component can be suppressed (supported) by the convex portion.

Thus, even when an impact is applied to the circuit board, the electronic component can be prevented from being separated from the circuit board, whereby the electronic component can be prevented from falling from the circuit board

Further, in this invention, the convex portion has a surface of an almost spherical shape.

According to the invention, since the convex portion has the almost spherical surface, the shape of the convex portion can be simplified and hence the manufacturing e procedure can be facilitated.

Further, in this invention, the convex portion has a surface of an almost spherical shape and a flat surface.

According to the invention, since the convex portion has the flat surface, the flat surface can be made in plane-contact with the top portion of the electronic component.

Thus, since the top portion can be stably pressed (supported) by the flat surface in a wide range thereof, even when an impact is applied to the circuit board, the electronic component can be more preferably prevented from being separated from the circuit board.

Further, in this invention, the top plate portion is provided with a through hole, and the convex portion crosses the through hole and has a width smaller than a width of the through hole.

According to the invention, the convex portion having a width smaller than the width of the through hole crosses the through hole of the top plate portion. Since the through hole can be formed in an arbitrary shape, the width of the convex portion can be suppressed to a smaller value as compared with a case where the convex portion is formed to have the almost spherical surface. Since the width of the convex portion is suppressed to the small value, the convex portion can be made close to the corner portion (edge portion) of the top plate portion.

Thus, for example, the convex portion can suppress (support) the top portion of the electronic component mounted near the corner portion of the top plate portion, whereby the application range of the convex portion can be enlarged.

Further, in this invention, the convex portion is configured to have a shape that the almost spherical surface thereof is cut so as to have the width smaller than the width of the through hole.

Thus, since a force applied at the time of deforming the convex portion can be dispersed, the distortion of the convex portion and the top plate can be suppressed at the time of deforming the convex portion.

Further, in this invention, a protruded size of the convex portion with respect to the top plate portion in the second state is larger than a downward movement size of the electronic component with respect to the circuit board in a state that the solder balls are melted by a reflow furnace and then solidified.

According to the invention, since the solder balls are melted by the reflow furnace and then solidified, the electronic component moves downward with respect to the circuit board by about 0.1 mm, for example.

Thus, in this invention, the protruded size of the convex portion is set to be larger than the downward movement size of the electronic component in a state that the convex portion is protruded on the circuit board side as the second state/

Therefore, since the convex portion is surely made in contact with the top portion of the electronic component, the top portion of the electronic component can be surely pressed (supported) by the convex portion.

### EFFECTS OF THE INVENTION

According to the electronic apparatus of the invention, since the convex portion deforms to the second state from the first state to thereby contact with the top portion of the electronic component, the top portion of the electronic component can be suppressed (supported) by the convex portion. Thus, even when an impact is applied to the circuit board, the electronic component can be prevented from being separated from the circuit board advantageously.

### BRIEF DESCRIPTION OF THE DRAWINGS

FIG. 1 shows a perspective view showing an opened state of an electronic apparatus according to the first embodiment of the invention.

FIG. 2 shows a sectional diagram showing the electronic apparatus in FIG. 1.

FIG. 3 (A) shows a plan view showing a convex portion of FIG. 1, and FIG. 3 (B) shows a sectional diagram along a line A-A in FIG. 3(A).

FIG. 4 shows a sectional diagram for explaining an example where an electronic component is mounted on a circuit board of the first embodiment.

FIG. 5 shows a sectional diagram showing an example where the convex portion of the first embodiment is disposed in a first state.

FIG. 6 (A) shows (A) is a plan view showing a convex portion according to the second embodiment of the invention, and FIG. 6(B) shows a sectional diagram along a line B-B in FIG. 6(A).

FIG. 7 (A) shows a plan view showing a convex portion according to the third embodiment of the invention, FIG. 7 (B) shows a sectional diagram along a line C-C in FIG. 7(A) and FIG. 7 (C) shows a sectional diagram along a line D-D in FIG. 7(A).

FIG. 8 shows a sectional diagram showing an electronic apparatus of a related art.

FIG. 9 shows a sectional diagram for explaining an example where an electronic component is mounted on a circuit board of the related art.

### MODES FOR CARRYING OUT THE INVENTION

Hereinafter, explanation will be made with reference to drawings as to an electronic apparatus 10 according to plural embodiments of the invention.

### First Embodiment

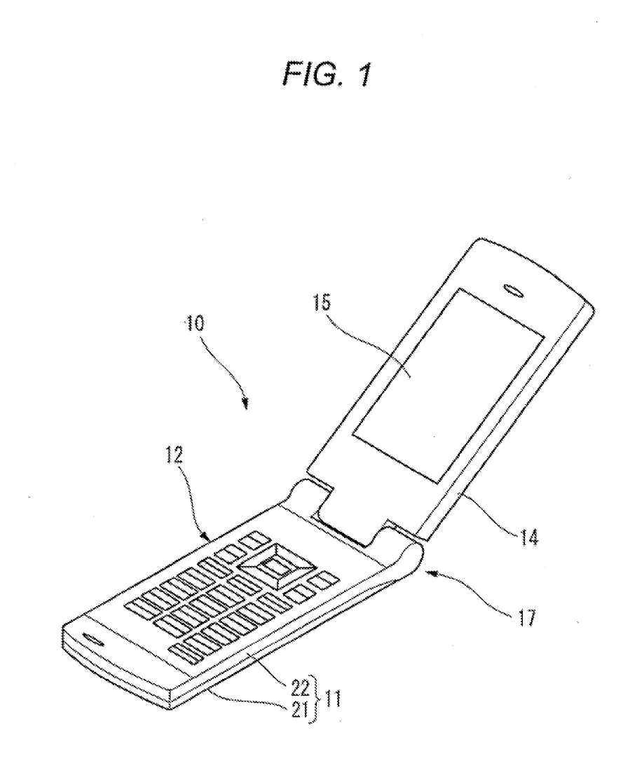

As shown in FIG. 1, the electronic apparatus 10 according to the first embodiment of the invention relates to a fold-type portable terminal which includes a lower housing 11 provided with an operation portion 12, an upper housing 14 provided with a display portion 15 and a coupling portion 17 for coupling the lower housing 11 and the upper housing 14 to each other so as to be foldable freely (opened/closed freely).

In the first embodiment, although the fold-type portable terminal is used as an example of the electronic apparatus 10, the electronic apparatus 10 is not limited to the fold-type portable terminal and the invention may be applied to other electronic apparatuses.

The lower housing 11 is formed as a housing shape by a lower cover 21 constituting the lower portion of the lower housing 11 and an upper cover 22 provided at the upper portion of the lower cover 21.

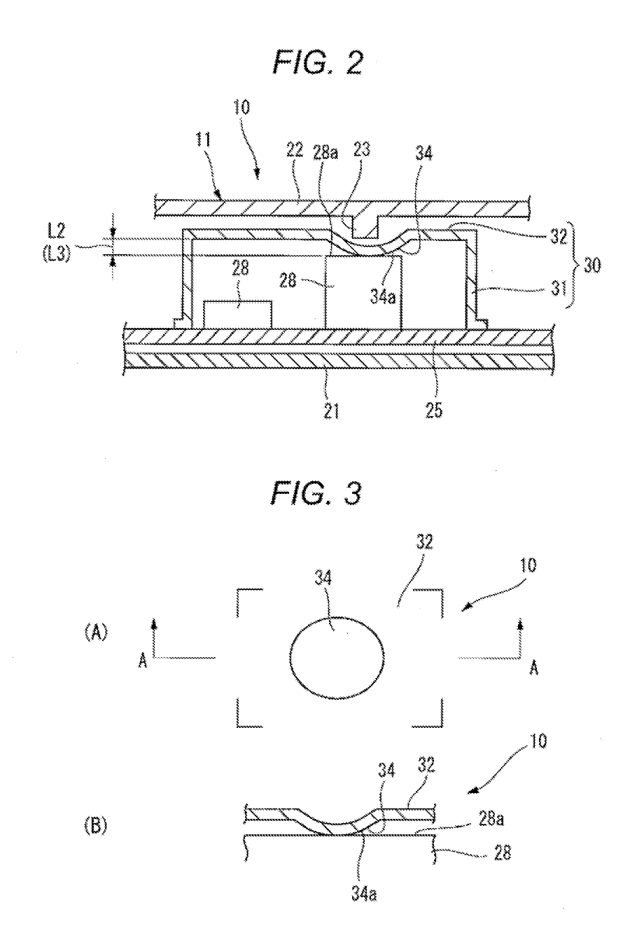

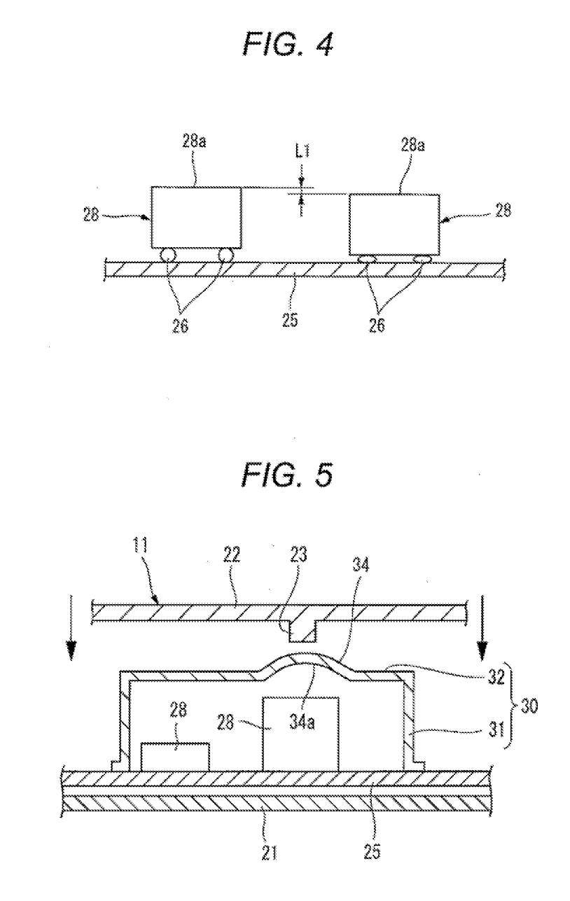

As shown in FIG. 2, the electronic apparatus 10 includes a circuit board 25 provided at the lower cover 21 of the lower housing 11, electronic components 28 mounted on the circuit board 25 via solder balls 26 (see FIG. 4), a cover member 30 for surrounding and covering the electronic components 28, and a convex portion 34 provided at the top plate portion 32 of the cover member 30.

As shown in FIG. 4, the electronic component 28 is placed on the circuit board 25 via the solder balls 26, and then the circuit board 25 is passed through a reflow furnace to melt, deform and solidify the solder balls 26 to thereby mount the electronic component 28 on the circuit board 25.

Since the solder balls 26 are melted, deformed and solidified, the electronic component 28 moves downward with respect to the circuit board 25. A size L1 of the downward movement of the electronic component 28 is about 0.1 mm, for example.

As shown in FIG. 2, the cover member 30 includes wall portions 31 which are mounted on the circuit board 25 and disposed around the electronic components 28 and a top plate portion 32 which is provided at the wall portions 31 and disposed above the top portion 28a of the electronic components 28 with a predetermined distance L2 from the top portion. The predetermined distance L2 between the top portion 28a and the top plate portion 32 almost same as the downward movement size L1 of the electronic component 28.

A convex portion 34 is provided near the center portion of the top plate portion 32.

As shown in FIGS. 3(A) and (B), the convex portion 34 is formed in a dome shape and hence has a spherical surface 34a. Since the convex portion 34 is configured to have the spherical surface 34a of the dome shape, the shape of the convex portion 34 can be simplified and the convex portion 34 can be formed easily.

The convex portion 34 is formed so as to be deformable (elastically deformable) to a second state (see FIG. 2) protruding on the circuit board 25 side from a first state (see FIG. 5) protruding in the direction opposite to the circuit board 25 side.

The convex portion 34 deformed in the second state is set in a manner that a protruded size L3 with respect to the top plate portion 32 is larger than the downward movement size L1 (see FIG. 4) of the electronic component 28 and larger than the predetermined distance L2 between the top portion 28a and the top plate portion 32.

Thus, the spherical surface 34a can be made in contact with the top portion 28a of the electronic component 28 by deforming the convex portion 34 in the second state.

When the spherical surface 34a of the convex portion 34 deformed in the second state is made in contact with the top portion 28a of the electronic component 28 in this manner, the top portion 28a of the electronic component 28 can be suppressed (supported) by the convex portion 34.

Thus, even when an impact is applied to the circuit board 25, the convex portion 34 can prevent the electronic component 28 from being separated from the circuit board 25, whereby the electronic component 28 can be prevented from falling from the circuit board 25.

The explanation will be made based on FIGS. 2, 4 and 5 as to an example for deforming the convex portion 34 to the second state from the first state.

First, as shown in FIG. 4, the electronic component 28 is mounted on the circuit board 25 via the solder balls 26 and also the cover member 30 (see FIG. 5) is mounted.

Next, as shown in FIG. 5, the circuit board 25 mounting the electronic component 28 and the cover member 30 thereon is attached to the lower cover 21 of the lower housing 11.

In this state, the convex portion 34 formed at the top plate portion 32 of the cover member 30 protrudes to the direction opposite to the circuit board 25 side as the first state.

The upper cover 22 is attached to the lower cover 21 of the lower housing 11 as shown by an arrow after attaching the circuit board 25 to the lower cover 21. At the time of attaching the upper cover 22 as shown by the arrow, the protrusion portion 23 of the upper cover 22 presses the convex portion 34 to the circuit board 25 side.

Thus, as shown in FIG. 2, the convex portion 34 deforms to the second state protruding on the circuit board 25 side from the first state. When the convex portion 34 deforms to the second state, the spherical surface 34a of the convex portion 34 contacts with the top portion 28a of the electronic component 28.

In this manner, since the protrusion portion 23 is formed at the upper cover 22, the protrusion portion 23 can deform the convex portion 34 in the second state at the time of attaching the upper cover 22 to the lower cover 21 as shown by an arrow.

Thus, the convex portion 34 can be easily deformed in the second state without increasing the working procedure at the time of the assembling.

In this embodiment, the convex portion 34 is formed to have the spherical surface by the following reasons. First, the shape of the convex portion 34 can be simplified and hence the manufacturing procedure can be facilitated. Further, when the convex portion 34 is pushed at the time of deforming the convex portion in the second state, the portion other than the convex portion 34 deforms unlikely. That is, when the convex portion has the spherical surface, the pushing force applied to the convex portion 34 is dispersed uniformly to the peripheral edge of the convex portion 34. Thus, there unlikely arises such a problem that, at the time of pushing the convex portion 34, the pushing force is applied to a part of the peripheral edge of the convex portion 34 to thereby also deform the portion other than the convex portion 34. Although the pushing force is likely dispersed as the shape of the convex portion is closer to the spherical shape, but the shape of the convex portion is not limited thereto. Even when the convex portion has an almost spherical shape, for example, an elliptical spherical shape close to the spherical shape, it can be expected that the pushing force will be dispersed to some extent.

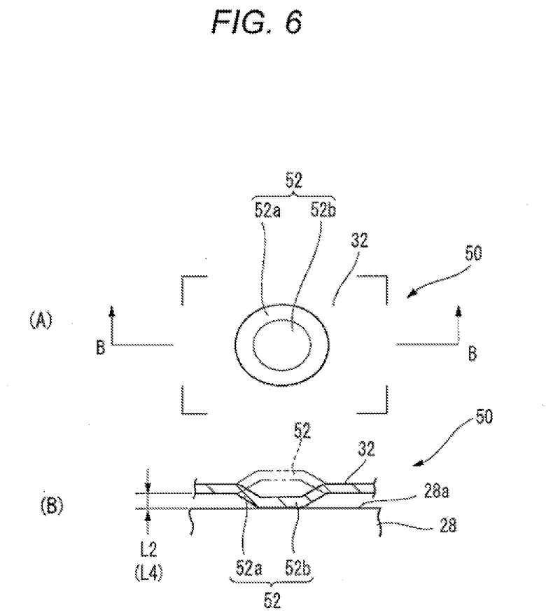

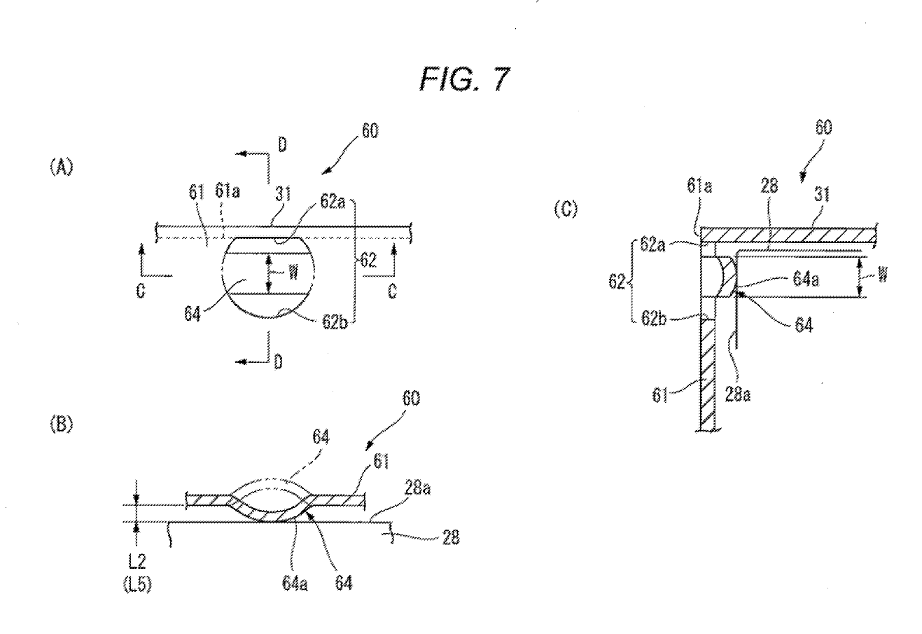

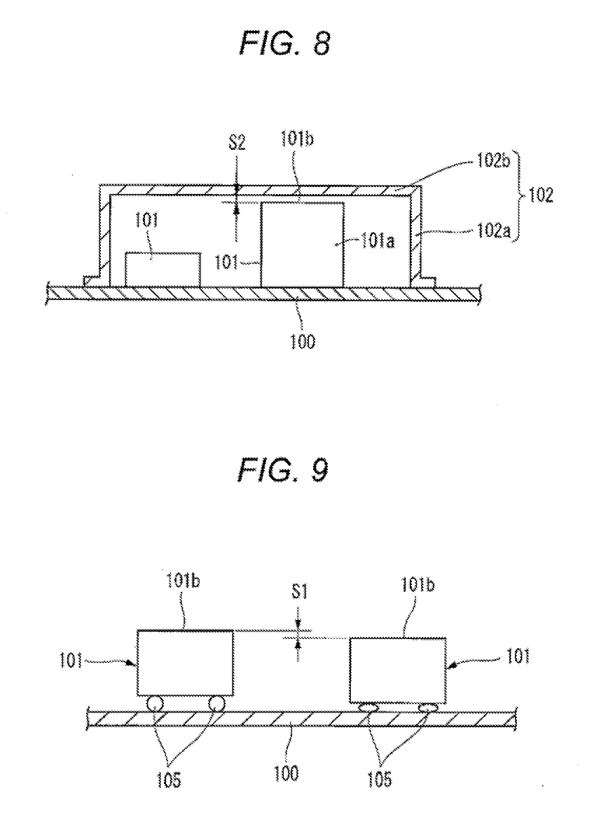

Next, the explanation will be made based on FIGS. 6 and 7 as to the electronic apparatus 50 according to the second embodiment and the electronic apparatus 60 according to the third embodiment. In each of the second embodiment and the third embodiment, members identical or similar to those of the electronic apparatus 10 according to the first embodiment are referred to by the common symbols, with explanation thereof being omitted.

As shown in FIGS. 6(A) and (B), in the electronic apparatus 50 according to the second embodiment, a convex portion 52 is provided in place of the convex portion 34 of the first embodiment but remaining configuration of this embodiment is same as that of the electronic apparatus 10 of the first embodiment.

The convex portion 52 is configured in a manner that each of the side portions thereof is formed in a dome shape and the top portion thereof is formed in a flat shape, whereby each of the side portions has a spherical surface 52a and the top portion has a flat surface 52b.

Like the convex portion 34 of the first embodiment, the convex portion 52 is formed so as to be deformable (elastically deformable) to a second state (state shown by steady lines) protruding on the circuit board 25 side from a first state (state shown by imaginary lines) protruding in the direction opposite to the circuit board 25 side.

The convex portion 52 deformed in the second state is set in a manner that a protruded size L4 with respect to the top plate portion 32 is larger than the downward movement size L1 (see FIG. 4) of the electronic component 28 and larger than the predetermined distance L2 between the top portion 28a and the top plate portion 32.

Thus, the flat surface 52b can be made in contact with the top portion 28a of the electronic component 28 by deforming the convex portion 52 in the second state.

In addition, the flat surface 52b can be made in plane-contact with the top portion 28a of the electronic component 28 by contacting the flat surface 52b to the top portion 28a of the electronic component 28.

Thus, since the top portion 28a can be stably pressed (supported) by the flat surface 52b in a wide range thereof, even when an impact is applied to the circuit board 25, the electronic component 28 can be more preferably prevented from being separated from the circuit board 25.

The shape of the flat surface 52b may be circle or may be other configuration. However, when the convex portion 52 is formed to have a circular shape, at the time of pushing the convex portion 52, the pushing force is applied uniformly to the peripheral edge of the flat surface 52b. Thus, the flat surface 52b is unlikely distorted after the pushing.

Further, in the second embodiment, the peripheral edge of the convex portion 52 has a circular shape. Thus, also when the convex portion 52 is pushed at the time. of deforming the convex portion in the second state, the portion other than the convex portion 52 deforms unlikely. That is, when the convex portion has the spherical surface, the pushing force applied to the convex portion 52 is dispersed uniformly to the peripheral edge of the convex portion 52. Thus, there unlikely arises such a problem that, at the time of pushing the convex portion 52, the pushing force is applied to a part of the peripheral edge of the convex portion 52 to thereby also deform the portion other than the convex portion 52. The shape of the peripheral edge of the convex portion 52 is not limited to a circle but may be an ellipse, for example. However, in order to prevent the deformation, the shape of the peripheral edge is desirably close to a circle among the ellipse.

### Third Embodiment

As shown in FIGS. 7(A) to (C), the electronic apparatus 60 according to the third embodiment includes a top plate portion 61 in place of the top plate portion 32 of the cover member 30 provided in the first embodiment but remaining configuration of this embodiment is same as that of the electronic apparatus 10 of the first embodiment.

The top plate portion 61 includes a through hole 62 provided near the wall portion 31 of the cover member 30 (that is, near the corner portion (edge portion) 61a of the top plate portion 61) and a convex portion 64 crossing the through hole 62.

The through hole 62 includes a straight line edge 62a formed in a straight-line shape and an arc edge 62b formed in an arc shape.

The arc edge 62b is provided at a portion near the wall portion 31 of the cover member 30 (that is, a portion near the corner portion (edge portion) 61a of the top plate portion 61).

The arc edge 62b is provided at a portion away from the wall portion 31.

Since the portion near the wall portion 31 is formed as the straight line edge 62a, as shown in FIGS. 7(A) and (C), the through hole 62 can be formed near the wall portion 31 (that is, near the corner portion (edge portion) 61a of the top plate portion 61)

The convex portion 64 has a spherical surface 64a crossing the through hole 62. Thus, when the spherical surface 64a is formed in a belt shape along the straight line edge 62a, the width W of the convex portion can be suppressed to a small value.

Since the width W of the convex portion 64 is suppressed to the small value, the spherical surface 64a can be made close to the straight line edge 62a.

Since the spherical surface 64a is made close to the straight line edge 62a, the spherical surface 64a can be made close (approach) to the wall portion 31 (that is, the corner portion (edge portion) 61a of the top plate portion 61).

As shown in FIG. 7(B), the convex portion 64 (that is, the spherical surface 64a) is formed to have an arc shape when viewed from the side direction thereof and is formed so as to be deformable (elastically deformable) to a second state (state shown by steady lines) protruding on the circuit board 25 side from a first state (state shown by imaginary lines) protruding in the direction opposite to the circuit board 25 side.

The convex portion 64 deformed in the second state is set in a manner that a protruded size L5 with respect to the top plate portion 61 is larger than the downward movement size L1 (see FIG. 4) of the electronic component 28 and larger than the predetermined distance L2 between the top portion 28a and the top plate portion 61.

Thus, the spherical surface 64a can be made in contact with the top portion 28a of the electronic component 28 by deforming the convex portion 64 in the second state.

When the spherical surface 64a of the convex portion 64 deformed in the second state is made in contact with the top portion 28a of the electronic component 28 in this manner, the top portion 28a of the electronic component 28 can be suppressed (supported) by the convex portion 64.

Thus, even when an impact is applied to the circuit board 25, the convex portion 64 can prevent the electronic component 28 from being separated from the circuit board 25, whereby the electronic component 28 can be prevented from falling from the circuit board 25.

Further, the through hole 62 is formed at the portion near the wall portion 31 (that is, the portion near the corner portion (edge portion) 61a of the top plate portion 61). Furthermore, the convex portion 64 is configured in a manner that the spherical surface 64a thereof crosses the through hole 62 to thereby form the convex portion 64 (spherical surface 64a) in the belt shape.

Since the spherical surface 64a of the convex portion 64 is formed in the belt shape, the width W of the convex portion can be suppressed to a smaller value as compared with the case where the convex portion 64 is formed in a spherical shape. Since the width W of the convex portion 64 is suppressed to the small value, the spherical surface can be made close to the corner portion (edge portion) 61a of the top plate portion 61.

Thus, for example, the convex portion 64 can also suppress (support) the top portion 28a of the electronic component 28 mounted near the corner portion (edge portion) 61a of the top plate portion 61, whereby the application range of the convex portion 64 can be enlarged.

In the third embodiment, the width of the convex portion 64 is set to be smaller than the width of the through hole 62. Thus, since the area of the convex portion 64 contacting with other portions becomes small, a force necessary for deforming the convex portion 64 into the second state can be suppressed.

Further, in the third embodiment, the convex portion 64 is configured to have a shape that a part of the spherical surface is cut. Thus, the pushing force applied to the convex portion 64 can be dispersed. As a result, since it becomes possible to avoid a state that a force is eccentrically applied to the end portion of the convex portion at the time of pushing the convex portion 64, the distortion of the shapes of the top plate portion 61 and the convex portion 64 can be prevented. Although the pushing force is likely dispersed as the shape of the convex portion is closer to the spherical shape, but the shape of the convex portion is not limited thereto. Even when the convex portion has an almost spherical shape, for example, an elliptical spherical shape close to the spherical shape, it can be expected that the pushing force will be dispersed to some extent.

In place of providing the through hole, the convex portion 64 itself may be narrowed. To be concrete, it is considered that the convex portion 64 is formed to have an elliptical spherical shape or to have a shape that a part of the spherical surface is cut. However, in this case, the applied force required at the time of deforming the convex portion 64 in the second state becomes larger. Further, since the shape of the convex portion 64 itself is distorted, the applied force can not be dispersed preferably. As a result, the top plate portion 61 and the convex portion 64 are likely distorted at the time of deforming the convex portion 64. Thus, this embodiment employs the aforesaid configuration.

In the third embodiment, although the through hole is formed to have the shape that a part of the circle is cut, the shape of the through hole is not limited thereto and may be formed to have an arbitrary shape.

In the third embodiment, although the convex portion 64 is set to have the constant width, the width of the convex portion is not limited thereto and may be changed on the way thereof so long as smaller than the width of the through hole.

The configurations of the electronic apparatuses 10, 50 and 60 are not limited to those of the first embodiment, second embodiment and third embodiment, respectively, and may be suitably changed or modified.

For example, although the fold-type portable terminal is employed as an example of the electronic apparatus 10 in each of the first to third embodiments, the electronic apparatus 10 is not limited to the fold-type portable terminal but may be applied to other types of electronic apparatuses.

Further, the shapes and configurations of the electronic apparatuses 10, 50, 60, the circuit board 25, the solder balls 26, the electronic component 28, the top portion 28a of the electronic component 28, the cover member 30, the top plate portions 32, 61, the convex portions 34, 52, the spherical surfaces 34a, 52a, 64a, the flat surface 52b, the through hole 62 and the convex portion 64 etc. employed in the first to third embodiments are not limited thereto and may be changed suitably.

This application is based on Japanese Patent Application (Japanese Patent Application No. 2010-054641) filed on Mar. 11, 2010 and the content thereof is incorporated herein by reference.

### EXPLANATION OF SIGNS

10, 50, 60 electronic apparatus
25 circuit board
26 solder ball
28 electronic component
28a top portion
30 cover member
32, 61 top plate portion
34, 52 convex portion
34a, 52a, 64a spherical surface
52b flat surface
62 through hole
64 convex portion

1. An electronic apparatus comprising:
a circuit board;
an electronic component mounted on the circuit board via solder balls;
a cover member mounted on the circuit board so as to surround and cover the electronic component; and
a convex portion provided at a top plate portion of the cover member, wherein the convex portion is deformable to a second state protruding on the circuit board side from a first state protruding in a direction opposite to the circuit board side, and the convex portion contacts with a top portion of the electronic component in the second state.

2. The electronic apparatus according to claim 1, wherein the convex portion has a surface of an almost spherical shape.

3. The electronic apparatus according to claim 1, wherein the convex portion has a surface of an almost spherical shape and a flat surface.

4. The electronic apparatus according to claim 1, wherein the top plate portion is provided with a through hole and the convex portion crosses the through hole and has a width smaller than a width of the through hole.

5. The electronic apparatus according to claim 4, wherein the convex portion is configured to have a shape that the almost spherical surface thereof is cut so as to have the width smaller than the width of the through hole.

6. The electronic apparatus according to claim 1, wherein a protruded size of the convex portion with respect to the top plate portion in the second state is larger than a downward movement size of the electronic component with respect to the circuit board in a state that the solder balls are melted by a reflow furnace and then solidified.
